(19) United States
(12) Patent Application Publication
(10) Pub. No.: US 2024/0188223 A1
(43) Pub. Date: Jun. 6, 2024

(54) MATERIAL DEPOSITION APPARATUS AND METHOD

(71) Applicant: Intel Corporation, Santa Clara, CA (US)

(72) Inventors: Zhixin XIE, Chandler, AZ (US); Jung Kyu HAN, Chandler, AZ (US); Gang DUAN, Chandler, AZ (US)

(21) Appl. No.: 18/060,581

(22) Filed: Dec. 1, 2022

(51) Int. Cl. H05K 3/28; B29C 70/70

(52) U.S. Cl. CPC H05K 3/284; B29C 70/70; B29L 2031/3406

(57) ABSTRACT

There may be provided an apparatus. The apparatus may include a first dispensing unit and a second dispensing unit. The apparatus may further include a connection assembly coupled to the first dispensing unit and the second dispensing unit in a manner such that a position of the first dispensing unit or the second dispensing unit relative to the other of said first dispensing unit or second dispensing unit may be adjustable via the connection assembly.

### TECHNICAL FIELD

Various aspects generally relate to an apparatus and a method. In particular, various aspects generally relate to an apparatus and a method for dispensing a plurality of (e.g. two or more) mold materials.

### BACKGROUND

A mold material is typically used to encapsulate components or packages (e.g. electronic or semiconductor packages). For example, in flip-chip packaging, a mold material may be employed to encapsulate various logic dies and chiplets.

Advancements in packaging technology may introduce numerous disparate components within a single package. However, if only single mold material is used, that mold material may not be capable of properly encapsulating all of the disparate components within the single package.

Accordingly, there may be a need for a system and method which solve at least the above-mentioned issue.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosure. In the following description, various aspects are described with reference to the following drawings, in which:

FIG. 1 shows a schematic side view of an apparatus, according to various aspects;

FIG. 2 shows a schematic perspective view of an apparatus which includes a first reservoir and a second reservoir, according to various aspects;

FIG. 3 shows a schematic side view of an apparatus which includes an actuation assembly, according to various aspects;

FIG. 4 shows a schematic top view of a substrate which includes a plurality of zones, according to various aspects; and

FIG. 5 is a flowchart of a method, according to various aspects.

### DETAILED DESCRIPTION

It will be understood that the aspects described below may be combined, for example, a part of one aspect may be combined with a part of another aspect.

It should be understood that the terms “on”, “over”, “top”, “bottom”, “down”, “side”, “back”, “left”, “right”, “front”, “lateral”, “side”, “up”, “down” etc., when used in the following description are used for convenience and to aid understanding of relative positions or directions, and not intended to limit the orientation of any device, or structure or any part of any device or structure. In addition, the singular terms “a”, “an”, and “the” include plural references unless context clearly indicates otherwise. Similarly, the word “or” is intended to include “and” unless the context clearly indicates otherwise.

Various aspects may generally relate to an apparatus (e.g. a molding tool, a material deposition system, or a structure formation system) and/or a method (e.g. a molding method, or a material deposition method) capable of dispensing a plurality of (e.g. two or more) mold materials simultaneously. For example, according to various aspects, the apparatus may include a plurality of (e.g. dual or two) feeders/throughs/liquid tube holders and a plurality of (e.g. dual or two) dispense units (e.g. including dispensing heads) with a physical linkage connection therebetween.

In particular, the apparatus and/or method according to the various aspects may be capable of simultaneously dispensing mold materials with different properties onto a single substrate (e.g. of a semiconductor package). For example, a first mold material dispensed according to (or by) the apparatus and/or method over (or on) a first zone (e.g. portion, region, etc.) of a substrate (e.g. a package substrate) may have a low coefficient of linear thermal expansion (CTE) to control warpage across the first zone of the substrate, another mold material dispensed by the apparatus and/or method over a second zone of the substrate may have a property of optical transparency, and yet another mold material dispensed by the apparatus and/or method over a third zone of the substrate may have good flowability so as to efficiently fill (e.g. gaps or pockets within and/or encapsulate) the third zone of the substrate. In other words, the apparatus and/or method according to the various aspects may segregate mold functions at specific locations (e.g. zones) of a package (e.g. substrate). Accordingly, the apparatus and/or method according to the various aspects may enable a much wider application of mold materials in (e.g. more complicated) heterogeneous packages (e.g. substrates). The apparatus and/or method according to the various aspects may save (or reduce) materials development cycle times and may increase process throughput. Moreover, a package processed by the apparatus and/or method according to the various aspects may have an interpenetrated interface between adjacent mold materials of different material compositions on a package.

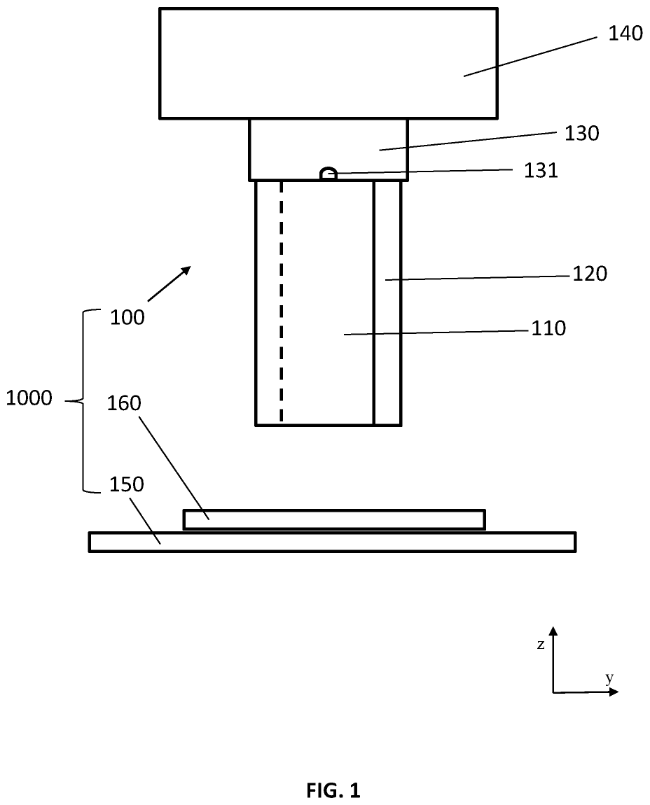

FIG. 1 shows a schematic side view of an apparatus 100, according to various aspects.

According to various aspects, there may be provided the apparatus 100 (e.g. a material deposition system).

According to various aspects, the apparatus 100 may include a first dispensing unit 110 and a second dispensing unit 120. For case of illustration, various aspects may refer to the apparatus 100 as including two dispensing units (e.g. the first dispensing unit 110 and the second dispensing unit 120). Nevertheless, it is understood that various aspects described as such are not limited thereto. Thus, for example, the apparatus 100 according to various aspects may include any other plural number (e.g. three, four, five, etc.) of dispensing units.

According to various aspects, the apparatus 100 may include a connection assembly 130 coupled or connected to the first dispensing unit 110 and the second dispensing unit 120. The connection assembly 130 may enable or allow a position of the first dispensing unit 110 relative to the second dispensing unit 120, or vice versa (e.g. a position of the second dispensing unit 120 relative to the first dispensing unit 110), to be adjusted or changed or moved. In particular, according to various aspects, with the connection assembly 130, the first dispensing unit 110 and the second dispensing unit 120 may be brought towards each other or moved away from each other (e.g. with an intended or predetermined space or gap therebetween the first dispensing unit 110 and the second dispensing unit 120). As an example, the connection assembly 130 may include or may be one or more linkage(s) (which may herein be referred to as a “linkage movement mechanism”) configured or arranged in a manner so as to enable the first dispensing unit 110 to be movable relative to the second dispensing unit 120, or vice versa. The linkage movement mechanism may be connected or coupled to any suitable portion or region of each of the first dispensing unit 110 and the second dispensing unit 120, for example, to a respective reservoir (described in detail later) of the first dispensing unit 110 and/or the second dispensing unit 120, a dispensing body or main body (e.g. main frame, outer case, etc.) of the first dispensing unit 110 and/or the second dispensing unit 120, etc. Further, the linkage movement mechanism may be, but is not limited to being, connected or coupled (e.g. anchored) to an external structure or fixture (e.g. wall, frame, etc.).

According to various aspects, the connection assembly 130 may include (e.g. further include) a retaining element 131 configured to or for retaining or locking the position of the first dispensing unit 110 or the second dispensing unit 120 relative to the other of said first dispensing unit 110 or second dispensing unit 120. As an example, the retaining element 131 may include one or more of: a locking arm/bar, a fastener (e.g. bolt, screw, etc.), a hydraulic/pneumatic locking or retaining mechanism, etc., or any other suitable retaining element. According to various aspects, once (or after) an intended or predetermined position (e.g. distance, space, gap, etc.) of the first dispensing unit 110 relative to the second dispensing unit 120 has been obtained or attained (e.g. upon or after adjustment via the connection assembly 130), the retaining element 131 of the connection assembly 130 may lock or retain the first dispensing unit 110 at the intended or predetermined position relative to the second dispensing unit 120. According to various aspects, when the position of the first dispensing unit 110 relative to the second dispensing unit 120 is locked or retained via the retaining element 131, the first dispensing unit 110 and the second dispensing unit 120 may be immovable relative to each other.

According to various aspects, the apparatus 100 may include (e.g. further include) an actuation assembly 140 configured to actuate or move the first dispensing unit 110 and/or the second dispensing unit 120 (e.g. individually, simultaneously, or in tandem/as a single/unified assembly/arrangement/system, etc.). In particular, the actuation assembly 140 may be configured to move the first dispensing unit 110 and/or the second dispensing unit 120 along at least one or both of a first direction parallel (e.g. substantially parallel) to a horizontal plane (e.g. lateral plane, x-y plane, etc.) of the apparatus 100 (or of a platform 150 of the apparatus 100, described in detail later) and/or a second direction perpendicular (e.g. substantially perpendicular) to the first direction (e.g. axially or along a z-y plane or z-x plane of the apparatus 100).

As an example, according to various aspects, the actuation assembly 140 may be connected or coupled (e.g. directly connected to coupled or indirectly connected or coupled) to cither (or only one) of the first dispensing unit 110 or the second dispensing unit 120. Accordingly, when the connection assembly 130 includes the retaining element 131 and when the position of the first dispensing unit 110 relative to the second dispensing unit 120 is retained via the retaining element 131, the actuation assembly 140 coupled to and actuating either (or only one) of the first dispensing unit 110 or the second dispensing unit 120 may consequently cause the other of the first dispensing unit 110 or the second dispensing unit 120 to move in tandem. As another example, according to various other aspects, the actuation assembly 140 may be connected or coupled to both (or each of the) first dispensing unit 110 and the second dispensing unit 120. For example, according to various other aspects, the actuation assembly 140 may include a first actuation unit coupled to and configured to actuate the first dispensing unit 110 and may further include a second actuation unit coupled to and configured to actuate the second dispensing unit 120 (e.g. independently from the first actuation unit). In other words, according to various other aspects, each of the first actuation unit and the second actuation unit of the actuation assembly 140 may be configured to individually or independently actuate or move the first dispensing unit 110/second dispensing unit 120, respectively (i.e. when the position of the first dispensing unit 110 relative to the second dispensing unit 120 is not retained via a corresponding retaining element 131). As such, according to various other aspects, the first actuation unit may cause the first dispensing unit 110 to move in a first direction while the second actuation unit may cause the second dispensing unit 120 to move in a second direction which may be the same or different from the first direction. Moreover, according to various other aspects, both the first dispensing unit 110 and the second dispensing unit 120 may be moved or actuated at a same time/simultaneously, by way of the first actuation unit and second actuation unit of the actuation assembly 140.

According to various aspects, each of the first dispensing unit 110 and the second dispensing unit 120 may be configured to dispense a respective material (e.g. a first mold material and a second mold material). Accordingly, the first mold material and second mold material may be included in the apparatus 100. According to various aspects, the first mold material may be a different material from the second mold material. In other words, a material composition of the first mold material may be different from a material composition of the second mold material. For example, the first mold material (e.g. pure substance or mixture) may be an entirely different material from the second mold material (e.g. pure substance or mixture). As another example, the first mold material (e.g. mixture) may have at least one element (e.g. of the mixture) being different from the second mold material (e.g. pure substance or mixture). According to various aspects, each of the first mold material and the second mold material may be or may include, for example, polymer, resin, etc. In particular, each of the first mold material and the second mold material may be of a similar or same type/form/state. For example, both the first mold material and the second mold material may be a liquid or liquid-based mold material. As another example, both the first mold material and the second mold material may be a granular or granular-based mold material. Accordingly, when both the first mold material and the second mold material are liquid or liquid-based mold materials, both the first dispensing unit 110 and the second dispensing unit 120 may each be a liquid mold dispenser. On the other hand, when both the first mold material and the second mold material are granular mold materials, both the first dispensing unit 110 and the second dispensing unit 120 may each be a granular mold dispenser. Accordingly, according to various aspects, the apparatus 100 may be configured or capable or dispensing two different mold materials (e.g. two chemically distinct mold materials, e.g. of similar or same type/form/state) simultaneously or at a same time (e.g. onto a substrate 160, described in detail later), thereby leading to time-saving and/or increased process throughput (e.g. during a semiconductor packaging process).

According to various aspects, the first dispensing unit 110 may include a first reservoir for or configured to contain the first mold material. The first dispensing unit 110 may further include a first dispensing head (e.g. nozzle) fluidly connected to the first reservoir for or configured to dispense the first mold material. The second dispensing unit 120 may include a second reservoir for or configured to contain the second mold material. The second dispensing unit 120 may further include a second dispensing head fluidly connected to the second reservoir for or configured to dispense the second mold material. According to various aspects, the second reservoir may be distinct from the first reservoir. For example, a partitioning formation (e.g. portioning wall) may partition an inner space of a container or enclosure into the first reservoir and the second reservoir. As another example, the first reservoir may include or may be a first container defining an inner space while the second reservoir may include or may be a second container separate (in other words, a different entity) from the first container that defines a separate inner space. Accordingly, the first mold material and the second mold material respectively held or contained within the first reservoir and the second reservoir may not mix or come into contact (i.e. within the apparatus 100).

With reference to FIG. 1, the apparatus 100 may further include the platform 150 (e.g. a substrate-support platform) configured to support a substrate 160 (e.g. a package substrate) thereon.

According to various aspects, the apparatus 100 including at least the first dispensing unit 110, the second dispensing unit 120, and the connection assembly 130 may form or may be referred to as a “dispensing assembly”.

According to various aspects, an apparatus 1000 (e.g. a structure formation system) may include the dispensing assembly and the platform 150. The dispensing assembly of the apparatus 1000 may be configured to form at least one mold structure on a substrate 160 (e.g. on the platform 150) by dispensing a first mold material over the platform 150 and by dispensing a second mold material over the platform 150.

According to various aspects, the apparatus 1000 may include (e.g. further include) the substrate 160 disposed or placed on the platform 150 (e.g. on a substrate-support surface or upper surface or the platform 150).

According to various aspects, the first dispensing unit 110 (i.e. of the apparatus 100/the apparatus 1000) may be configured to dispense the first mold material while the second dispensing unit 120 (i.e. of the apparatus 100/the apparatus 1000) may be configured to dispense the second mold material, over the platform 150, for or so as to form at least one mold structure (e.g. at least one integrated mold structure and/or a plurality of discrete mold structures) over the platform 150 (or on the substrate 160 disposed or placed on the platform 150).

According to various aspects, the platform 150 may be divided into or may include a plurality of regions. The substrate 160, on the other hand, may be divided into or may include a corresponding plurality of zones (e.g. functional zones). The plurality of zones of the substrate 160 may be aligned with the plurality of regions of the platform 150 (e.g. when the substrate 160 is placed thereon). Each zone of the substrate 160 may correspond to or may be a region or part of the substrate 160 requiring a material (e.g. a mold material) with a specific or predetermined material property to be dispensed thereon. For example, the substrate 160 may include a first zone requiring the first mold material to be dispensed thereon and may further include a second zone requiring the second mold material (i.e. having a different material composition, and hence different material property, from the first mold material) to be dispensed thereon.

The actuation assembly 140 may be configured to actuate the first dispensing unit 110 and the second dispensing unit 120 along at least one or both of a first direction parallel to the platform 150 (or the substrate-support surface or upper surface of the platform 150) and/or a second direction substantially perpendicular to the platform 150 (or the substrate-support surface or upper surface of the platform 150). Accordingly, the actuation assembly 140 may be configured to actuate the first dispensing unit 110 over a first region of the plurality of regions of the platform 150 (and/or over a first zone of the substrate 160 placed thereon) so that the first dispensing unit 110 may dispense or may be capable of dispensing the first mold material over the first region of the platform 150 (e.g. and, in turn, over the first zone of the substrate 160). Further, the actuation assembly 140 may be configured to actuate the second dispensing unit 120 over a second region of the plurality of regions of the platform 150 (and/or over a second zone of the substrate 160) so that the second dispensing unit 120 may dispense or may be capable of dispensing the second mold material over the second region of the platform 150 (e.g. and, in turn, the second zone of the substrate 160).

According to various aspects, by controlling or being able to adjust a relative position of a plurality of dispensing units (e.g. the first dispensing unit 110 and the second dispensing unit 120), different mold combination(s) (e.g. different mold materials) may be dispensed (e.g. simultaneously) at distinct or discrete or separate or different locations (e.g. regions/zones) over the platform 150 (or across/over a substrate 160 disposed or placed on the platform 150).

According to various aspects, the apparatus 100 and/or the apparatus 1000 may include a controller (e.g. processor) (not shown) configured to control (e.g. automatically or electronically control) any one or more of the actuation assembly 140 (e.g. to actuate the first dispensing unit 110 and/or the second dispensing unit 120), the connection assembly 130 (e.g. to adjust a position of the first dispensing unit 110 and the second dispensing unit 120 relative to each other), and/or the first dispensing unit 110 and/or the second dispensing unit 120 (e.g. to dispense the first mold material and/or the second mold material), etc.

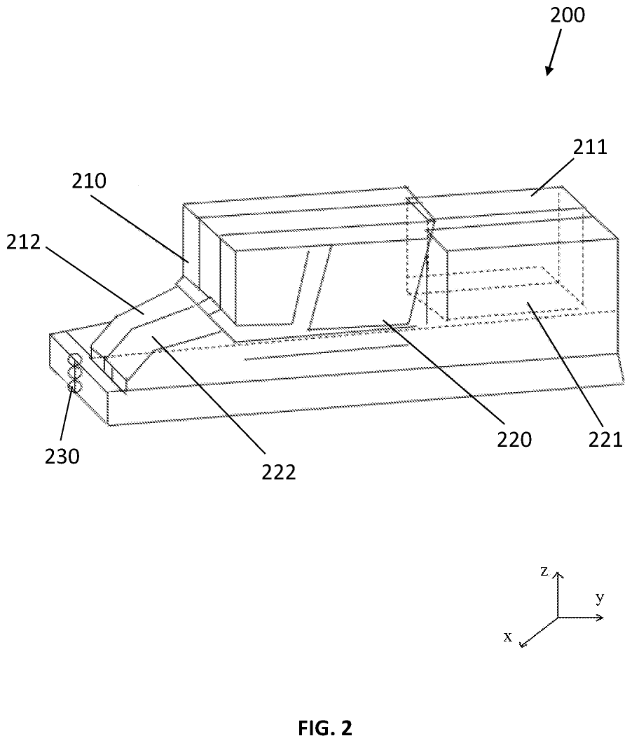

FIG. 2 shows a schematic perspective view of an apparatus 200 which includes a first reservoir 211 and a second reservoir 221, according to various aspects.

The apparatus 200 (e.g. a material deposition system) may contain any one or more or all the features and/or limitations of the apparatus 100 of FIG. 1. In the following, the apparatus 200 is described with like reference characters generally referring to the same or corresponding parts/features of the apparatus 100 of FIG. 1. The description of the part(s)/feature(s) made with respect to the apparatus 200 may also be applicable with respect to the apparatus 100, and vice versa.

As in the apparatus 100 of FIG. 1, the apparatus 200 of FIG. 2 may include a first dispensing unit 210, a second dispensing unit 220 and a connection assembly 230 coupled or connected to the first dispensing unit 210 and the second dispensing unit 220.

As shown, the connection assembly 230 of the apparatus 200 may be interposed between (e.g. directly between) the first dispensing unit 210 and the second dispensing unit 220. For example, the connection assembly 230 may be an adjustable linkage (e.g. linkage movement mechanism) that enables movement (e.g. translational or linear movement along 3-degrees of freedom/along X, Y and/or Z axis of the apparatus 200) or adjustment of a position of the first dispensing unit 210 or the second dispensing unit 220 relative to the other of said first dispensing unit 210 or second dispensing unit 220. According to various aspects, movement or adjustment of a position of the first dispensing unit 210 and second dispensing unit 220 relative to each other (e.g. via the connection assembly 230) may be accomplished manually or through controllable powered drive mechanisms (e.g. stepper motor(s), pneumatic actuator(s), hydraulic, electric driver(s), or any other type of drive mechanisms).

Further, as shown, each of the first dispensing unit 210 and the second dispensing unit 220 may include a respective reservoir (e.g. first reservoir 211/second reservoir 221) in fluidic connection to a respective dispensing head (e.g. first dispensing head 212/second dispensing head 222). As shown, the first reservoir 211 (e.g. a primary trough) may be discrete or a separate reservoir from the second reservoir 221 (e.g. a secondary trough). Accordingly, when a position of the first dispensing unit 210 relative to the second dispensing unit 220 is adjusted via the connection assembly 230, a position of the first reservoir 211 and first dispensing head 212 relative to the second reservoir 221 and the second dispensing head 222 will be adjusted accordingly or correspondingly. That is, the first dispensing unit 210 with the first reservoir 211 and the first dispensing head 212 may move as a single unit independent of movement of the second dispensing unit 220 with the second reservoir 221 and the second dispending head 222, or vice versa.

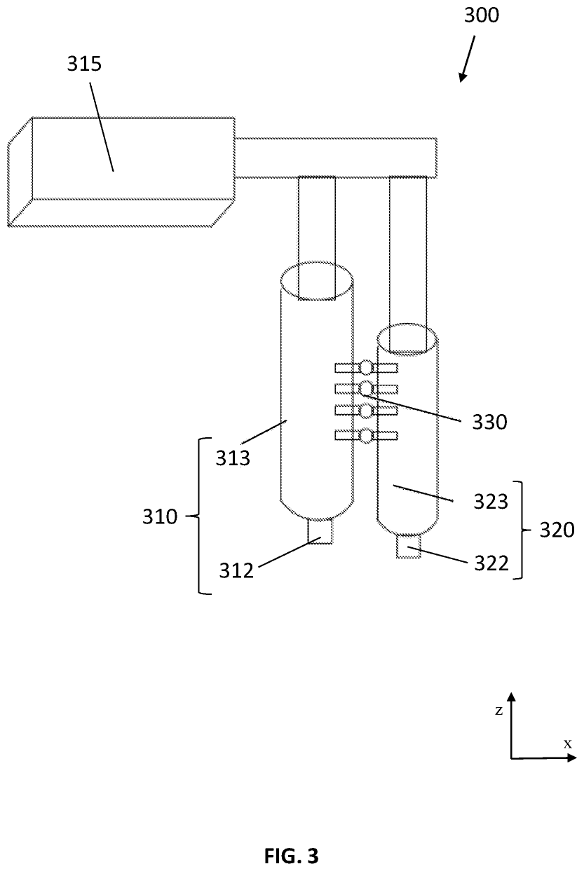

FIG. 3 shows a schematic side view of an apparatus 300 which includes an actuation assembly 315, according to various aspects.

The apparatus 300 (e.g. a material deposition system) may contain any one or more or all the features and/or limitations of the apparatus 100 of FIG. 1 and/or the apparatus 200 of FIG. 2. In the following, the apparatus 300 is described with like reference characters generally referring to the same or corresponding parts/features of the apparatus 100 of FIG. 1 and/or the apparatus 200 of FIG. 2. The description of the part(s)/feature(s) made with respect to the apparatus 300 may also be applicable with respect to the apparatus 100 and/or the apparatus 200, and vice versa.

As in the apparatus 100 of FIG. 1, the apparatus 300 of FIG. 3 may include a first dispensing unit 310 and a second dispensing unit 320. As shown, the first dispensing unit 310 may include a first dispensing head 312 mounted to a first dispensing body 313. The second dispensing unit 320 may include a second dispensing head 322 mounted to a second dispensing body 323. Further, each of the first dispensing unit 310 and the second dispensing unit 320 may include a respective reservoir (e.g. internal reservoir) respectively containing or configured to contain or for containing a first mold material and a second mold material, respectively, therein. As an example, the reservoir (e.g. internal reservoir) may be within the first dispensing body 313 and the second dispensing body 323, respectively.

As shown, the apparatus 300 may further include an actuation assembly 315 (e.g. which may include a motor control box) configured to or for actuating or moving the first dispensing unit 310 and/or the second dispensing unit 320.

As shown, as in the apparatus 200 of FIG. 2, the apparatus 300 of FIG. 3 may include (e.g. further include) a connection assembly 330 interposed between the first dispensing unit 310 and the second dispensing unit 320. In particular, as shown, the connection assembly 330 of the apparatus 300 of FIG. 3 may include a plurality of linkages (e.g. linkage movement mechanism) coupled to the first dispensing body 313 and the second dispensing body 323 of the first dispensing unit 310 and the second dispensing unit 320, respectively. According to various aspects, the plurality of linkages (e.g. linkage movement mechanism) may be moved (e.g. rotated) relative to each other to move (e.g. rotate) the first dispensing body 313 (i.e. with the first dispensing head 312) and the second dispensing body 323 (i.e. with the second dispensing head 322) relative to each other and/or may be extended or retracted (e.g. via telescopic or sliding joints) to move (e.g. extend or retract) the first dispensing body 313 and the second dispensing body 323 away or towards each other.

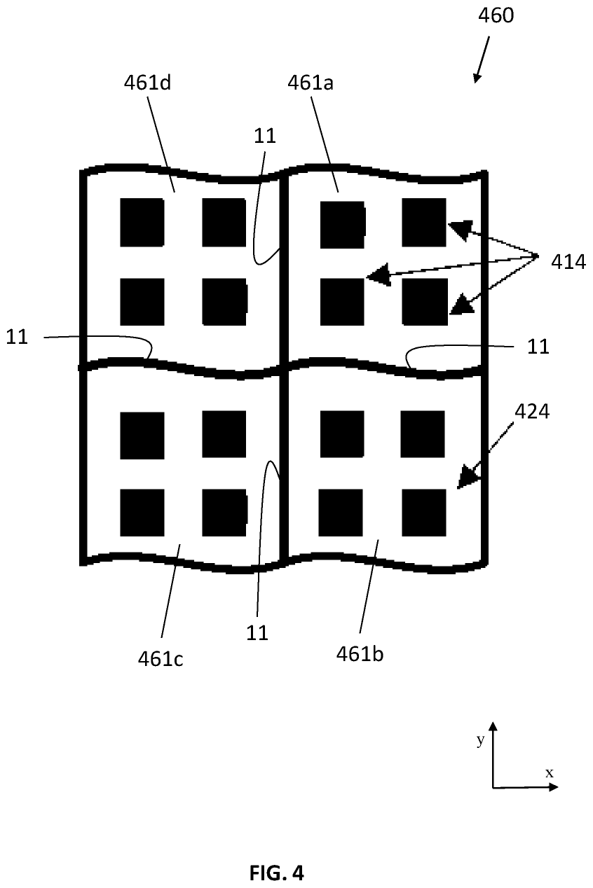

FIG. 4 shows a schematic top view of a substrate 460 (e.g. a package substrate) which includes a plurality of zones 461, according to various aspects.

The substrate 460 may contain any one or more or all the features and/or limitations of the substrate 160 of FIG. 1. In the following, the substrate 460 is described with like reference characters generally referring to the same or corresponding parts/features of the substrate 160 of FIG. 1. The description of the part(s)/feature(s) made with respect to the substrate 460 may also be applicable with respect to the substrate 160, and vice versa.

According to various aspects, the substrate 460 may be or may include a circuit board (e.g. printed circuit board, flexible circuit board, etc.), a chip (e.g. electronic chip), a package (e.g. semiconductor package, package substrate), a wafer, etc.

As shown, the substrate 460 may include a plurality of zones 461, for example, four zones 461a, 461b, 461c, 461c. In particular, as shown, each pair of adjacent or neighboring (e.g. immediately adjacent or neighboring) zones may share a common boundary 11.

Each zone 461 of the substrate 460 may correspond to a part or region of the substrate 460 requiring or which may only accept a material (e.g. mold material) with a specific or predetermined material property to be dispensed thereon. For example, a first zone 461a may include bumps with extremely small bump pitch and may, thus, require or be able to only accept a material (e.g. a first mold material 414) with good flowability (e.g. a low/lower filler loading material with high/higher coefficient of linear thermal expansion (CTE)), while a second zone 461b may require or be able to only accept a high/higher filler loading material (e.g. a second mold material 424) with low/lower CTE than the first mold material.

According to various aspects, the apparatus 100, 200 or 300 and/or apparatus 1000 may be capable of dispensing both a low/lower filler loading material with high/higher CTE (e.g. the first mold material) and a high/higher filler loading material with low/lower CTE (e.g. the second mold material) simultaneously, onto the first zone 461a and the second zone 462a of the substrate 460. Accordingly, a variety of combination of materials (e.g. mold materials) may be realized or dispensed in one (e.g. simultaneous) step or process, with the apparatus 100, 200 or 300 and/or apparatus 1000. Moreover, different materials dispensed onto neighboring zones may form strong bonds (or a strongly bonded interface) with/between each other (e.g. at a shared/common boundary 11) as a result of co-polymerization, thereby minimizing or preventing any potential delamination between adjoining materials (e.g. chemically distinct materials) dispensed by the apparatus 100, 200 or 300 and/or apparatus 1000 (e.g. onto the substrate 460). For example, when the different materials simultaneously dispensed by the apparatus 100, 200 or 300 and/or apparatus 1000 are different resins (e.g. have different chemical compositions), co-polymerization of the different resins (e.g. in one step/within a same time period) may result in strong bonding interface, and/or gradual transition of CTE, between adjacent and adjoining resins (e.g. of different chemical compositions), thereby resulting in a more robust package.

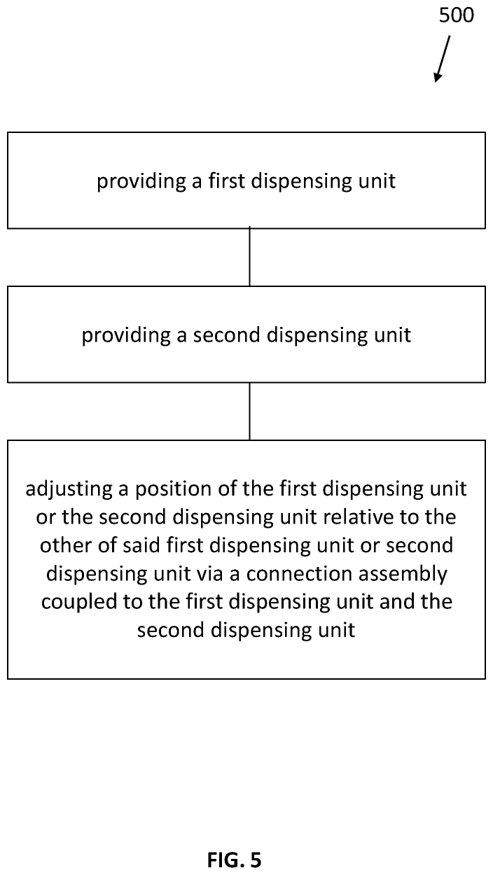

FIG. 5 is a flowchart of a method 500 (e.g. a material deposition method), according to various aspects.

According to various aspects, the method 500 (e.g. material deposition method) may be performed with or using or by the apparatus 100, 200 or 300 and/or the apparatus 1000.

According to various aspects, the method 500 may include providing the first dispensing unit 110, 210 or 310 and the second dispensing unit 120, 220 or 320.

The method 500 may include (e.g. further include) adjusting a position of the first dispensing unit 110, 210 or 310 or the second dispensing unit 120, 220 or 320 relative to the other of said first dispensing unit 110, 210 or 310 or second dispensing unit 120, 220 or 320 via the connection assembly 130, 230 or 330 coupled to the first dispensing unit 110, 210 or 310 and the second dispensing unit 120, 220 or 320.

The method 500 may include (e.g. further include) dispensing the first mold material from the first dispensing unit 110, 210 or 310 (e.g. onto the substrate 160 or 460). The method 500 may include (e.g. further include) dispensing the second mold material from the second dispensing unit 120, 220 or 320 (e.g. onto the substrate 160 or 460). According to various aspects, the first mold material and the second mold material may be dispensed simultaneously or at a same time from the first dispensing unit 110, 210 or 310 and the second dispensing unit 120, 220 or 320, respectively.

The method 500 may include (e.g. further include) retaining a position of the first dispensing unit 110, 210 or 310 or the second dispensing unit 120, 220 or 320 relative to the other of said first dispensing unit 110, 210 or 310 or second dispensing unit 120, 220 or 320 via the retaining element, for example, before dispensing the first mold material from the first dispensing unit 110, 210 or 310 and before dispensing the second mold material from the second dispensing unit 120, 220 or 320.

The method 500 may include (e.g. further include) actuating, via the actuation assembly 140, the first dispensing unit 110, 210 or 310 and the second dispensing unit 120, 220 or 320 along one or both of a first direction (e.g. parallel to a transverse/lateral plane of the apparatus 100, 200 or 300 or parallel to a substrate-support surface of the platform 150) and/or a second direction substantially perpendicular to the first direction. According to various aspects, the first dispensing unit 110, 210 or 310 and the second dispensing unit 120, 220 or 320 may be actuated, while the position of the first dispensing unit 110, 210 or 310 or the second dispensing unit 120, 220 or 320 relative to the other of said first dispensing unit 110, 210 or 310 or second dispensing unit 120, 220 or 320 is retained via the retaining element. According to various other aspects, when the position of the first dispensing unit 110, 210 or 310 or the second dispensing unit 120, 220 or 320 relative to the other of said first dispensing unit 110, 210 or 310 or second dispensing unit 120, 220 or 320 is not retained via the retaining element, the first dispensing unit 110, 210 or 310 and the second dispensing unit 120, 220 or 320 may be individually or independently actuable via respective actuation unit(s) (i.e. first actuation unit and/or second actuation unit) of the actuation assembly 140.

The method 500 may include (e.g. further include) providing the substrate 160 or 460. The substrate 160 or 460 may include the plurality of zones 461. The substrate 160 or 460 may be provided on the substrate-support surface (e.g. upper surface) of the platform 150, with the plurality of zones 461 of the substrate 160 or 460 aligned with (e.g. directly over or resting on) a corresponding plurality of regions of the platform 150. According to various aspects, a first zone of the plurality of zones 461 of the substrate 160 or 460 may share a boundary with an adjacent second zone of the plurality of zones 461 of the substrate 160 or 460.

The method 500 may include (e.g. further include) dispensing the first mold material from the first dispensing unit 110, 210 or 310 onto the first zone of the plurality of zones 461 of the substrate 160 or 460. The method 500 may include (e.g. further include) dispensing the second mold material from the second dispensing unit 120, 220 or 320 onto the second zone of the plurality of zones 461 of the substrate 160 or 460. For example, the first dispensing unit 110, 210 or 310 may be actuated (i.e. by the actuation assembly 140) over the first zone of the substrate, while the first dispensing unit 110, 210 or 310 dispenses the first mold material over the first zone of the substrate, and the second dispensing unit 120, 220 or 320 may be actuated (i.e. by the actuation assembly 140) over the second zone of the substrate, while the second dispensing unit 120, 220 or 320 dispenses the second mold material over the second zone of the substrate 160 or 460.

According to various aspects, the first mold material and the second mold material may each (or both) be dispensed as a liquid or in a liquid form, or (e.g. according to various other aspects) as a granular or in a granular form, onto the first zone and the second zone of the substrate 160 or 460. According to various aspects, the first mold material and the second mold material may have different material compositions from one other.

According to various aspects, the method 500 may include (e.g. further include) curing the first mold material and the second mold material (e.g. simultaneously) on the substrate.

Accordingly, the first mold material and the second mold material may co-polymerize to form a bonded interface therebetween (e.g. along the boundary between the first zone and the second zone of the substrate).

While the disclosure has been particularly shown and described with reference to specific aspects, it should be understood by those skilled in the art that various changes, modification, variation in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

1. An apparatus comprising:
a first dispensing unit configured to dispense a first mold material;
a second dispensing unit configured to dispense a second mold material;
a connection assembly coupled to the first dispensing unit and the second dispensing unit in a manner such that a position of the first dispensing unit or the second dispensing unit relative to the other of said first dispensing unit or second dispensing unit is adjustable via the connection assembly; and
a platform configured to support a package substrate.

2. The apparatus of claim 1,
wherein the connection assembly comprises a retaining element configured to retain the position of the first dispensing unit or the second dispensing unit relative to the other of said first dispensing unit or second dispensing unit.

3. The apparatus of claim 1, further comprising:
an actuation assembly configured to actuate the first dispensing unit and the second dispensing unit along one or both of a first direction substantially parallel to a lateral plane of the platform or a second direction substantially perpendicular to the first direction.

4. The apparatus of claim 1,
wherein the first dispensing unit comprises a first reservoir configured to contain the first mold material;
wherein the second dispensing unit comprises a second reservoir configured to contain the second mold material.

5. The apparatus of claim 4, further comprising:
the first mold material in the first reservoir; and
the second mold material in the second reservoir;
wherein a material composition of the first mold material is different from a material composition of the second mold material.

6. The apparatus of claim 5,
wherein each of the first mold material and the second mold material is in a liquid form.

7. The apparatus of claim 1,
wherein the first dispensing unit and the second dispensing unit are configured to dispense the first mold material and the second mold material simultaneously onto the package substrate.

8. An apparatus comprising:
a dispensing assembly comprising:
a first dispensing unit,
a second dispensing unit, and
a connection assembly coupled to the first dispensing unit and the second dispensing unit in a manner such that a position of the first dispensing unit or the second dispensing unit relative to the other of said first dispensing unit or second dispensing unit is adjustable via the connection assembly; and
a substrate-support platform;
wherein the dispensing assembly is configured to form at least one mold structure on a substrate on the substrate-support platform by dispensing a first mold material over the substrate-support platform and by dispensing a second mold material over the substrate-support platform.

9. The apparatus of claim 8,
wherein the connection assembly comprises a retaining element configured to retain the position of the first dispensing unit or the second dispensing unit relative to the other of said first dispensing unit or second dispensing unit

10. The apparatus of claim 8, further comprising:
an actuation assembly configured to actuate the first dispensing unit and the second dispensing unit along one or both of a first direction parallel to the substrate-support platform or a second direction substantially perpendicular to the first direction.

11. The apparatus of claim 10,
wherein the actuation assembly comprises a first actuation unit configured to actuate the first dispensing unit and a second actuation unit configured to actuate the second dispensing unit, wherein the first dispensing unit and the second dispensing unit are individually actuable via respective actuation unit.

12. The apparatus of claim 8,
wherein the substrate-support platform is divided into a plurality of regions for alignment with a corresponding plurality of zones of the substrate;
wherein the actuation assembly is configured (i) to actuate the first dispensing unit over a first region of the plurality of regions for the first dispensing unit to dispense the first mold material over the first region and (ii) to actuate the second dispensing unit over a second region of the plurality of regions for the second dispensing unit to dispense the second mold material over the second region.

13. The apparatus of claim 8,
wherein the first dispensing unit and the second dispensing unit are configured to dispense the first mold material and the second mold material simultaneously.

14. The apparatus of claim 8, further comprising:
the substrate on the substrate-support platform.

15. The apparatus of claim 14,
wherein the substrate comprises one of a circuit board, a chip, a package, or a wafer.

16. A method comprising:
providing a first dispensing unit;
providing a second dispensing unit;
adjusting a position of the first dispensing unit or the second dispensing unit relative to the other of said first dispensing unit or second dispensing unit via a connection assembly coupled to the first dispensing unit and the second dispensing unit;
dispensing a first mold material from the first dispensing unit onto a package substrate; and
dispensing a second mold material from the second dispensing unit onto the package substrate.

17. The method of claim 16, further comprising:
retaining a position of the first dispensing unit or the second dispensing unit relative to the other of said first dispensing unit or second dispensing unit via a retaining element, before dispensing the first mold material from the first dispensing unit and dispensing the second mold material from the second dispensing unit.

18. The method of claim 16, further comprising:
actuating, via an actuation assembly, the first dispensing unit and the second dispensing unit along one or both of a first direction or a second direction substantially perpendicular to the first direction.

19. The method of claim 16, further comprising:
retaining a position of the first dispensing unit or the second dispensing unit relative to the other of said first dispensing unit or second dispensing unit via a retaining element, before dispensing the first mold material from the first dispensing unit and dispensing the second mold material from the second dispensing unit; and
actuating, via an actuation assembly, the first dispensing unit and the second dispensing unit along one or both of a first direction or a second direction substantially perpendicular to the first direction;
wherein the first dispensing unit and the second dispensing unit are actuated while the position of the first dispensing unit or the second dispensing unit relative to the other of said first dispensing unit or second dispensing unit is retained via the retaining element.

20. The method of claim 16,
wherein the package substrate comprises a first zone and an adjacent second zone,
the method further comprising:
dispensing the first mold material from the first dispensing unit onto the first zone;
dispensing the second mold material from the second dispensing unit onto the second zone;
wherein the first zone of the package substrate shares a boundary with the second zone of the package substrate;
wherein the first mold material and the second mold material have different material compositions; and
curing the first mold material and the second mold material dispensed on the substrate in a manner such that the first mold material co-polymerizes with the second mold material on the substrate along the boundary between the first zone and the second zone of the package substrate.
